(19) United States
(12) Patent Application Publication
(10) Pub. No.: US 2010/0032733 A1
(43) Pub. Date: Feb. 11, 2010

(54) SEMICONDUCTOR DEVICE AND MANUFACTURING METHOD THEREOF

(75) Inventors: Satoru ITOU, Hyogo (JP); Yasutoshi Okuno, Kyoto (JP); Takashi Nakabayashi, Leuven (BE)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/580,573

(22) Filed: Oct. 16, 2009

Related U.S. Application Data
(63) Continuation of application No. PCT/JP2008/003614, filed on Dec. 5, 2008.

(30) Foreign Application Priority Data
Feb. 19, 2008 (JP) 2008-037142

(51) Int. Cl. H01L 29/78; H01L 21/20

(52) U.S. Cl. 257/288; 438/478; 257/E29.255; 257/E21.131

(57) ABSTRACT

A semiconductor device includes: a semiconductor substrate having an element formation region containing impurities of a first conductivity type; a gate electrode formed on the element formation region with a gate insulating film interposed therebetween; and a silicon alloy layer formed on a lateral side of the gate electrode in the element formation region, and containing impurities of a second conductivity type. A boundary layer containing impurities of the second conductivity type is formed between the silicon alloy layer and the element formation region.

### CROSS-REFERENCE TO RELATED APPLICATIONS

This is a continuation of Application PCT/JP2008/003614, filed on Dec. 5, 2008. The PCT application claims priority to Japanese Patent Application No. 2008-037142 filed on Feb. 19, 2008. The entire contents of these applications are hereby incorporated by reference.

### BACKGROUND

This disclosure generally relates to semiconductor devices and manufacturing methods thereof. More particularly, this disclosure relates to semiconductor devices having strain introduced in channel regions, and manufacturing methods thereof.

In recent years, attempts have been made to increase the operating speed of Metal-Insulator-Semiconductor (MIS) transistors by improving carrier mobility by introducing crystal strain into channel regions of the MIS transistors. One of the attempts is a method for epitaxially growing a material having a different lattice constant from that of silicon in source and drain portions of a MIS transistor (see, for example, U.S. Pat. No. 6,319,782).

For example, in p-type transistors, a silicon-germanium alloy layer containing p-type impurities is epitaxially grown in trenches formed on the lateral sides of a gate electrode. Since silicon germanium, which is an alloy of silicon and germanium, has a larger lattice constant than that of silicon, uniaxial compressive strain of a gate length direction is applied to a channel of a MIS transistor. This increases hole mobility, thereby improving the driving capability of p-type MIS transistors.

On the other hand, in n-type transistors, a silicon-carbon alloy layer containing n-type impurities is epitaxially grown. Since silicon carbide, which is an alloy of silicon and carbon, has a smaller lattice constant than that of silicon, uniaxial tensile strain of a gate length direction is applied to a channel. This increases electron mobility, thereby improving the driving capability of n-type MIS transistors.

### SUMMARY

However, conventional semiconductor devices have the following problems. A silicon alloy layer, which is made of silicon germanium, silicon carbide, or the like, does not have a lattice match with a silicon substrate. Thus, defects are generated near the interface between the silicon alloy layer and the silicon substrate during a cooling process after growing the silicon alloy layer, or during an activation annealing process.

The defects are located in a depletion region that is formed near the interface between the silicon alloy layer and the silicon substrate. Thus, trap-assisted tunneling occurs, causing movement of electrons from a valence band to a conduction band. As a result, junction leakage of a MIS transistor increases, resulting in an increased leakage current during a standby state of a circuit.

The present disclosure can solve the above problems, and can implement a semiconductor device in which a junction leakage current, resulting from defects that are generated in the interface between a silicon alloy layer and a substrate, is reduced in a MIS transistor including a silicon alloy layer for introducing strain into a channel.

An example semiconductor device has a boundary layer formed between a silicon alloy layer and an element formation region, and having the same conductivity type as that of the silicon alloy layer.

More specifically, an example semiconductor device includes: a semiconductor substrate having an element formation region containing impurities of a first conductivity type; a gate electrode formed on the element formation region with a gate insulating film interposed therebetween; a silicon alloy layer formed on a lateral side of the gate electrode in the element formation region, and containing impurities of a second conductivity type; and a boundary layer formed between the silicon alloy layer and the element formation region, and containing impurities of the second conductivity type.

The example semiconductor device includes a boundary layer formed between the silicon alloy layer and the element formation region, and containing impurities of the second conductivity type. Thus, the interface between the element formation region and the boundary layer becomes a pn junction interface. Thus, the distance from defects resulting from a lattice mismatch between the silicon alloy layer and the semiconductor substrate to the pn junction interface where a depletion region extends increases by the thickness of the boundary layer. This reduces occurrence of trap-assisted tunneling caused by defects being located in the depletion region, whereby degradation in leakage current characteristics can be suppressed.

An example method for manufacturing a semiconductor device includes the steps of: (a) sequentially forming a gate insulating film and a gate electrode on an element formation region formed in a semiconductor substrate and containing impurities of a first conductivity type; (b) forming a trench on a lateral side of the gate electrode in the element formation region; (c) forming a boundary layer containing impurities of a second conductivity type on side and bottom surfaces of the trench; and (d) after the step (c), epitaxially growing a silicon alloy layer, containing impurities of the second conductivity type, in the trench.

The example manufacturing method of the semiconductor device includes the step of forming a boundary layer containing impurities of the second conductivity type on the side and bottom surfaces of the trench. Thus, the distance from defects that are generated in the silicon alloy layer to a pn junction increases by the thickness of the boundary layer. Thus, no defect is located in a depletion region, whereby occurrence of trap-assisted tunneling can be suppressed. As a result, a semiconductor device having improved leakage current characteristics can be implemented.

### BRIEF DESCRIPTION OF THE DRAWINGS

FIG. 1 is a cross-sectional view showing a semiconductor device according to an embodiment.

FIG. 2 is an energy band diagram near a boundary layer of the semiconductor device according to the embodiment.

FIG. 3 is an energy band diagram in a semiconductor device having no boundary layer.

FIG. 4 is a graph showing leakage current characteristics of the semiconductor device according to the embodiment, in comparison with conventional semiconductor devices.

FIGS. 5A, 5B, 5C, and 5D are step-by-step cross-sectional views illustrating a manufacturing method of the semiconductor device according to the embodiment.

FIG. 6 is a graph showing an example of an impurity profile near the boundary layer of the semiconductor device according to the embodiment.

FIG. 7 is a cross-sectional view showing a semiconductor device according to a modification.

FIG. 8 is a graph showing an example of an impurity profile near a boundary layer of the semiconductor device according to the modification.

### DETAILED DESCRIPTION

### Embodiment

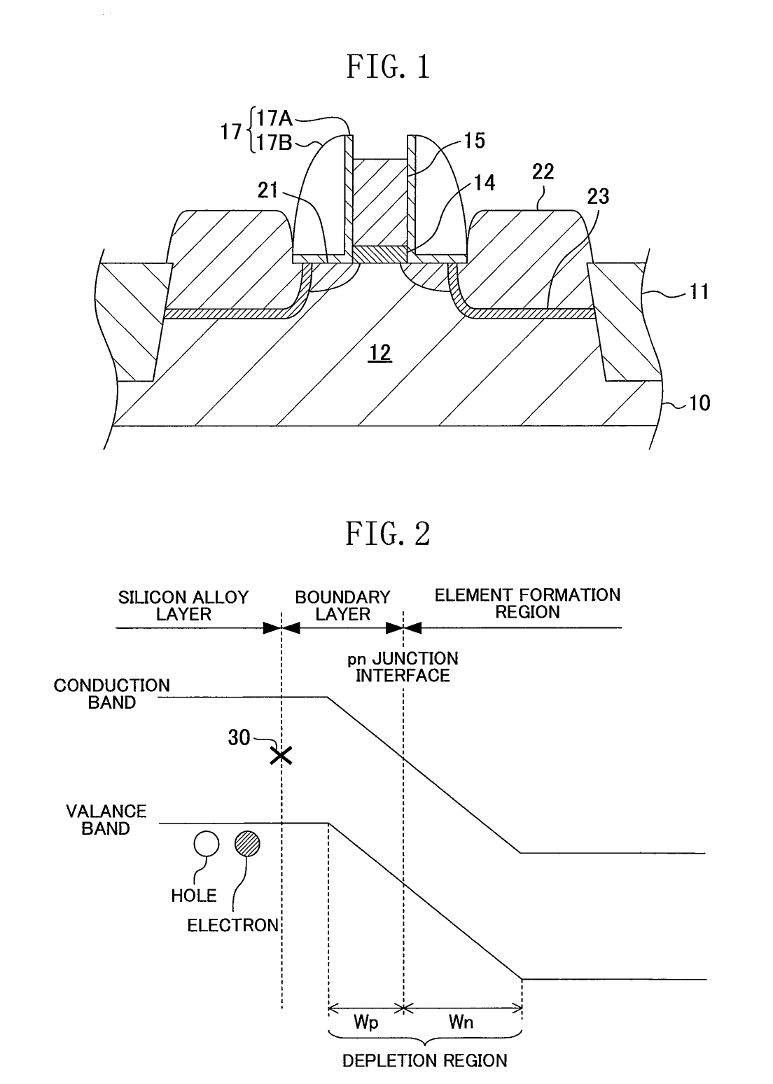

An embodiment will be described below with reference to the accompanying drawings. FIG. 1 shows a cross-sectional structure of a semiconductor device according to the present embodiment. The present embodiment will be described below with respect to a p-type MIS transistor as an example. Components that do not directly relate to the present disclosure, such as a silicide layer, an interlayer insulating film, contacts, and interconnects, are not shown in FIG. 1.

An element formation region 12, which is isolated by element isolation regions 11 as shallow trench isolations (STIs), is formed in an n-type semiconductor substrate 10 such as a silicon substrate.

A gate electrode 15 is formed on the element formation region 12 with a gate insulating film 14 interposed therebetween. Sidewall spacers 17 are formed adjacent to the gate electrode 15. In the present embodiment, each sidewall spacer 17 is formed by an L-shaped sidewall 17A and an outer sidewall 17B.

A p-type extension region 21 is formed on both lateral sides of the gate electrode 15 in the element formation region 12. In the present embodiment, the p-type extension regions 21 contain about 3×10²⁰ cm⁻³ of p-type impurities. A trench is formed in a region outside each p-type extension region 21. A silicon alloy layer 22 containing p-type impurities is formed in each trench. In the present embodiment, the silicon alloy layers 22 are made of an alloy of silicon and germanium (silicon germanium) which is formed by epitaxial growth, and contain about 1×10²¹ cm⁻³ of p-type impurities. Silicon germanium has a larger lattice constant than that of silicon. Thus, a compressive stress of a gate length direction is applied to a channel region that is formed in a portion corresponding to the gate electrode 15 in the element formation region 12. This increases hole mobility, thereby improving the driving capability of the p-type MIS transistor.

Moreover, in the semiconductor device of the present embodiment, a boundary layer 23 doped with p-type impurities is formed in a portion located on the side and bottom surfaces of each trench in the element formation region 12. Thus, the interface between each boundary layer 23 and the element formation region 12 becomes a pn junction interface. As described below, it is preferable that the boundary layers 23 have a p-type impurity concentration of 5×10¹⁹ cm⁻³ or more, and a thickness of 5 nm or more.

FIG. 2 is an energy band diagram near each boundary layer 23 in the case where a negative drain voltage is applied to a drain of the MIS transistor of the present embodiment. A thickness W of a depletion region that is produced by applying a voltage to a pn junction is represented by the following expression (1).

$$W = {W}_{n} + {W}_{p} = \sqrt{\frac{2 {ɛ}_{s} {ɛ}_{0} ( Vd + V )}{{qN}_{D} {N}_{A}} ( {N}_{D} + {N}_{A} )} \qquad ( 1 )$$

In this expression, Wₚ indicates the thickness of a depletion layer extending to the p-type semiconductor layer side, and Wₙ indicates the thickness of a depletion layer extending to the n-type semiconductor layer side. ∈₀ indicates the vacuum dielectric constant, ∈ₛ indicates a relative dielectric constant of silicon, N_{A} indicates an acceptor concentration, N_{D} indicates a donor concentration, q indicates electric charge, V indicates a voltage that is applied to the pn junction, V_{d} is a built-in voltage. Wₚ, Wₙ, N_{A}, and N_{D} have a relation shown by the following expression (2) (see, for example, S. M. Sze, Physics of Semiconductor Devices).

N_{A}Wp=N_{D}Wn (2)

Moreover, V_{d} can be represented by the following expression (3). In the expression (3), k_{B} is Boltzmann's constant, and Ni is an intrinsic carrier concentration of silicon.

$$Vd = \frac{{k}_{B} T}{q} ln ( \frac{{N}_{D} {N}_{A}}{{Ni}^{2}} ) \qquad ( 3 )$$

From the above expressions, the thickness Wₚ of the depletion layer extending from the interface between the element formation region 12 and the boundary layer 23 toward the silicon alloy layer 22 is about 3 nm in the case where the p-type impurity (acceptor) concentration in the boundary layer 23 is 5×10¹⁹ cm⁻³, the n-type impurity (donor) concentration in the element formation region 12 is 5×10¹⁸ cm⁻³, and the voltage applied to the pn junction is 1.2 V.

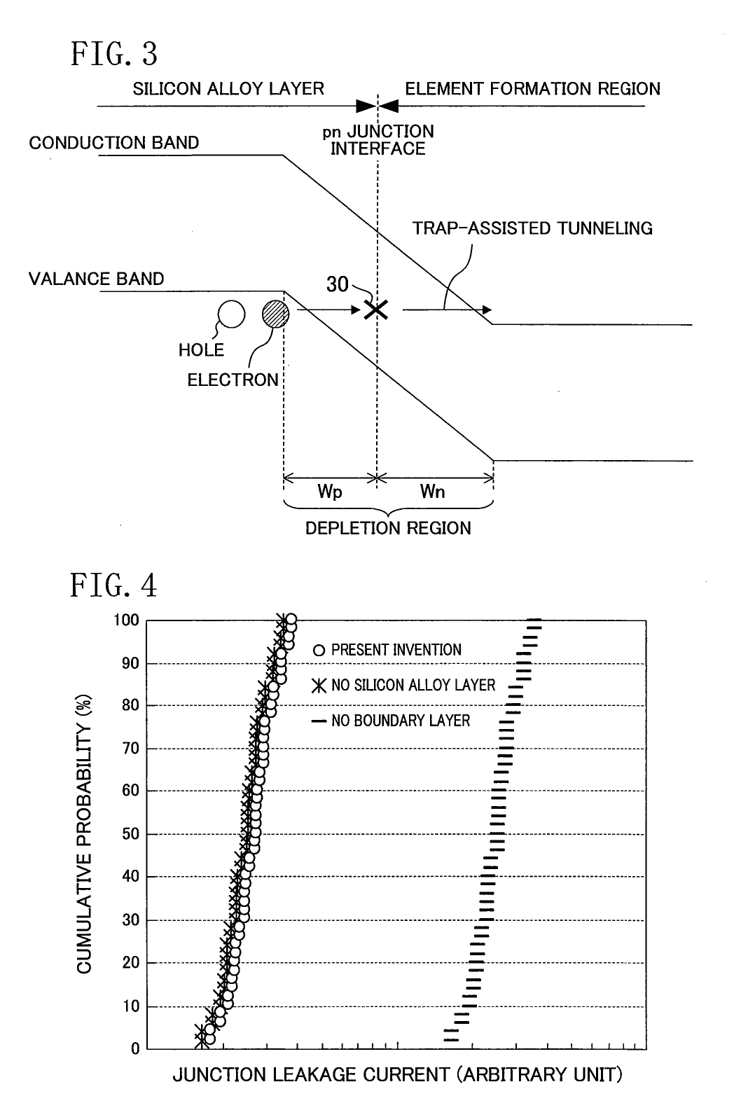

In the case where the silicon alloy layer 22 is epitaxially grown, defects 30 resulting from a lattice mismatch between silicon germanium and silicon are generated near the interface between silicon germanium and silicon during a cooling process after the growth, or during an activation annealing process. In the case where no boundary layer 23 is formed, the defects 30 are located in a depletion region, as shown in FIG. 3. This causes trap-assisted tunneling in which electrons move from a valence band to a conduction band. As a result, the junction leakage increases, causing an increase in leakage current during a standby state of a circuit.

In the semiconductor device of the present embodiment, however, since the boundary layer 23 having a thickness of 5 nm is formed, no defect 30 is located in the depletion region, and trap-assisted tunneling does not occur. As a result, as shown in FIG. 4, the junction leakage current can be suppressed to a lower level than that in conventional transistors in which a silicon alloy layer is formed with no boundary layer, and can be retained at substantially the same level as that in the case where no silicon alloy layer 22 is formed.

The thickness of the boundary layer 23 need only be larger than the thickness Wₚ of the depletion region extending from the pn junction interface toward the silicon alloy layer 22. Thus, no defect 30 is located in the depletion region. As described above, the thickness of the depletion region varies depending on the p-type impurity concentration in the boundary layer 23 and the n-type impurity concentration in the element formation region 12. Thus, the thickness of the boundary layer 23 can be set according to these impurity concentrations.

The higher the p-type impurity concentration in the boundary layer 23 is, the smaller the thickness Wₚ of the depletion region extending toward the silicon alloy layer 22 becomes, and the less the defects 30 are likely to be located in the depletion region. However, excessively increasing the p-type impurity concentration in the boundary layer 23 can increase diffusion of the p-type impurities into a region surrounding the boundary layer 23, and can result in an abnormal impurity concentration profile of the extension region 21 and the silicon alloy layer 22. Thus, it is preferable not to excessively increase the impurity concentration in the boundary layer 23 as compared to the impurity concentration in the silicon alloy layer 22. More specifically, the impurity concentration in the boundary layer 23 is preferably about 5×10¹⁹ cm⁻³ to about 3×10²⁰ cm⁻³.

Since the semiconductor device of the present embodiment is less susceptible to the defects 30, it is possible to increase the germanium concentration in the silicon alloy layer 22 to generate larger strain. This enables the driving capability of the transistor to be improved over conventional examples.

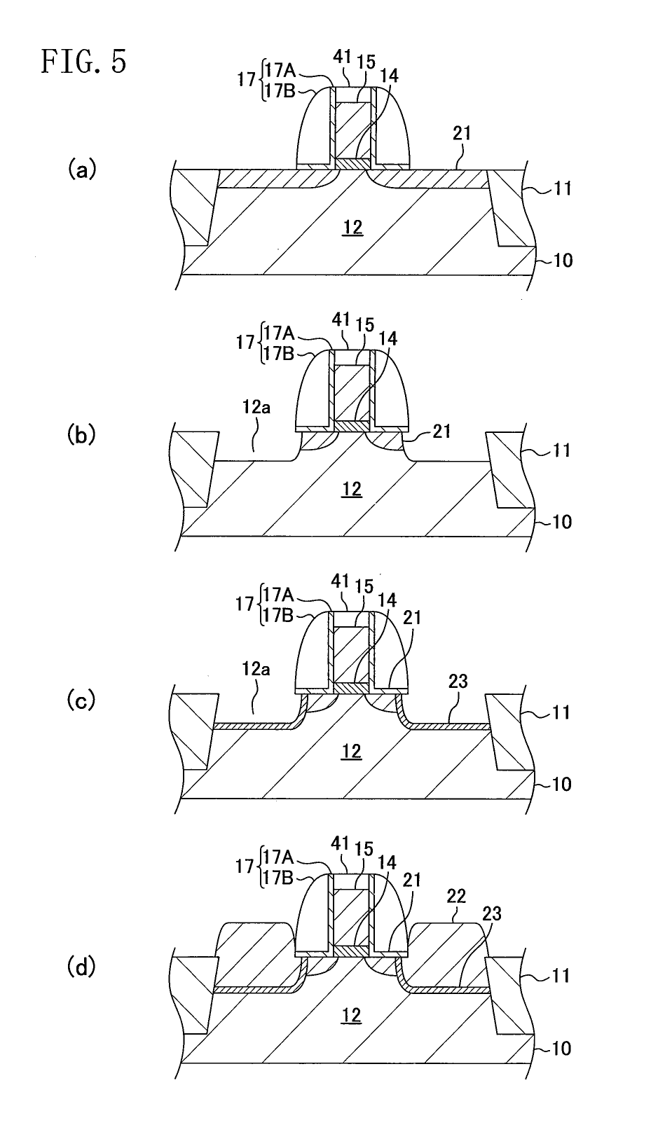

The semiconductor device of the present embodiment can be formed by a similar method to that of conventional semiconductor devices having silicon alloy layers for applying strain to a channel, except for forming the boundary layers 23. More specifically, as shown in FIG. 5A, the element formation region 12 isolated by the element isolation regions 11 is formed in the n-type silicon substrate 10. Next, the gate insulating film 14, the gate electrode 15, and an insulating film 41 that serves as a mask for epitaxial growth, are selectively formed on the element isolation region 12, and then, impurities are implanted to form the p-type extension regions 21. Then, the sidewall spacers 17, each formed by the L-shaped sidewall 17A and the outer sidewall 17B, are formed so as to cover the sidewalls of the gate electrode 15. Note that, instead of using the n-type substrate, n-type impurities may be implanted to form an n-type well.

Then, as shown in FIG. 5B, by using the gate electrode 15 having the sidewall spacers 17 formed thereon as a mask, the element formation region 12 is dry etched to form trench portions 12a. Note that, if the extension regions 21 can be secured, the trench portions 12a may be formed before forming the sidewall spacers 17. This enables a larger stress to be applied to the channel.

Then, as shown in FIG. 5C, portions located at the bottom and side surfaces of the trench portions 12a in the element formation region 12 are doped with p-type impurities, such as boron, to form the boundary layers 23.

Then, as shown in FIG. 5D, a silicon germanium layer containing p-type impurities is grown in each trench portion 12a having the boundary layer 23 formed therein, thereby forming the silicon alloy layers 22.

Then, although not shown in the figure, removal of the insulating film 41, silicidation of the gate electrode 15 and the silicon alloy layers 22, formation of interconnects, formation of contacts, and the like are performed as necessary.

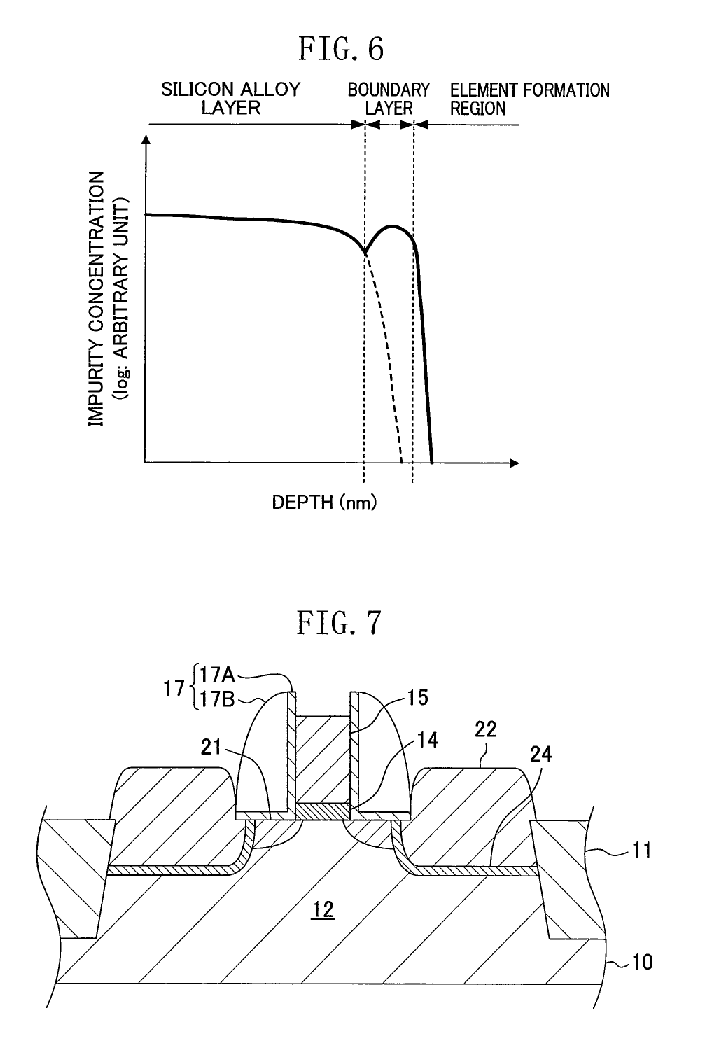

In the semiconductor device of the present embodiment, it is preferable that not only the bottom surface but also the side surfaces of each trench portion be uniformly doped with impurities to form the boundary layers 23. Thus, it is preferable to use a plasma doping method (see, for example, D. Lenoble et al., 2006 Symposium on VLSI Technology Digest of Technical Papers, p. 168) to form the boundary layers 23. FIG. 6 shows an example of an impurity concentration profile near the interface between the element formation region 12 and each boundary layer 23 in the case where the boundary layers 23 are formed by a plasma doping method.

Since the boundary layers 23 are formed by impurity doping, tails are produced on the element formation region 12 side. Moreover, such impurity doping causes movement of impurities due to thermal diffusion from the silicon alloy layer 22 side, movement of impurities due to thermal diffusion to the silicon alloy layer 22 side, or the like. Thus, the impurity concentration in the boundary layers 23 is not constant, and has a profile having a peak value as shown in FIG. 6. In this case, the impurity concentration need only be 5×10¹⁹ cm⁻³ or more in a region located at least 5 nm from the interface between the boundary layer 23 and the silicon alloy layer 22. This prevents defects from being located in the depletion regions, whereby the influence of trap-assisted tunneling can be suppressed.

(Modification of the Embodiment)

A modification example will be described below with reference to the drawings. FIG. 7 shows a cross-sectional structure of a semiconductor device according to the modification example. As shown in FIG. 7, a feature of the semiconductor device of the modification is that the semiconductor device includes boundary layers 24 formed by an epitaxial growth method.

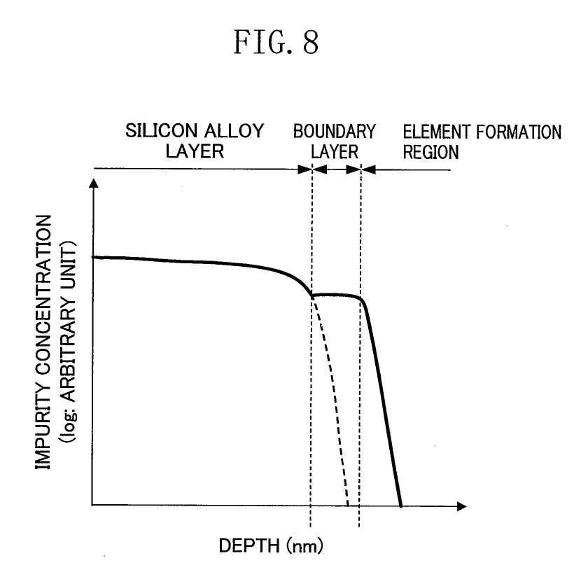

The boundary layers 24 can be formed by forming trenches on lateral sides of the gate electrode 15 in the element formation region 12, and then forming a silicon layer containing p-type impurities on the bottom and side surfaces of the trenches by an epitaxial growth method. Even when the boundary layers 24 are formed by an epitaxial growth method, the leakage current can be reduced as in the case where the boundary layers are formed by impurity doping. In the case where the boundary layers 24 are formed by an epitaxial growth method, the impurity concentration in the boundary layers 24 can be made substantially constant, as shown in FIG. 8.

Moreover, the boundary layers 24 are not limited to silicon, but may be made of any material that has a lattice match with silicon, and thus, generates no defect. For example, in the case of using silicon germanium for the silicon alloy layers 22, the boundary layers 24 can also apply strain to the channel if the boundary layers 24 are made of a silicon germanium layer containing a low germanium concentration.

Although the embodiment and the modification thereof were described with respect to a p-type MIS transistor, similar effects can be obtained also in an n-type MIS transistor. In the case of forming an n-type MIS transistor, n-type impurities, such as phosphorus, are used as the impurities contained in the silicon alloy layers and the boundary layers, and p-type impurities are used as the impurities contained in the element formation region. Moreover, the silicon alloy layers are made of an alloy of silicon and carbon (silicon carbide), or the like, so that a tensile stress of a gate length direction can be applied.

The semiconductor device and the manufacturing method thereof according to the present disclosure are useful as semiconductor devices which are capable of reducing a junction leakage current resulting from defects that are generated in the interface between a silicon alloy layer for introducing strain and a silicon substrate, and which have strain introduced into a channel region, and manufacturing methods thereof.

What is claimed is:

1. A semiconductor device comprising:
a semiconductor substrate having an element formation region containing impurities of a first conductivity type;
a gate electrode formed on the element formation region with a gate insulating film interposed therebetween;
a silicon alloy layer formed on a lateral side of the gate electrode in the element formation region, and containing impurities of a second conductivity type; and
a boundary layer formed between the silicon alloy layer and the element formation region, and containing impurities of the second conductivity type.

2. The semiconductor device of claim 1, wherein
the boundary layer has a larger thickness than a thickness of a depletion region extending from an interface between the boundary layer and the element formation region toward the silicon alloy layer.

3. The semiconductor device of clam 1, wherein
the silicon alloy layer has defects, and
a distance from the interface between the boundary layer and the element formation region to an end of a depletion region extending toward the silicon alloy layer is shorter than a distance from the interface to the defects.

4. The semiconductor device of claim 1, wherein
a concentration profile of the impurities of the second conductivity type in the boundary layer has a peak value.

5. The semiconductor device of claim 1, wherein
the boundary layer has a thickness of at least 5 nm, and contains at least 5×10¹⁹ cm⁻³ of the impurities of the second conductivity type.

6. The semiconductor device of claim 1, wherein
the silicon alloy layer contains p-type impurities as the impurities of the second conductivity type, and generates compressive strain of a gate length direction in a channel region formed in a portion corresponding to the gate electrode in the element formation region.

7. The semiconductor device of claim 6, wherein
the silicon alloy layer is made of silicon germanium.

8. The semiconductor device of claim 1, wherein
the silicon alloy layer contains n-type impurities as the impurities of the second conductivity type, and generates tensile strain of a gate length direction in a channel region formed in a portion corresponding to the gate electrode in the element formation region.

9. The semiconductor device of claim 8, wherein
the silicon alloy layer is made of silicon carbide.

10. A method for manufacturing a semiconductor device, comprising the steps of:
(a) sequentially forming a gate insulating film and a gate electrode on an element formation region formed in a semiconductor substrate and containing impurities of a first conductivity type;
(b) forming a trench on a lateral side of the gate electrode in the element formation region;
(c) forming a boundary layer containing impurities of a second conductivity type on side and bottom surfaces of the trench; and
(d) after the step (c), epitaxially growing a silicon alloy layer, containing impurities of the second conductivity type, in the trench.

11. The method of claim 10, wherein
in the step (c), the boundary layer is formed by plasma doping.

12. The method of claim 10, wherein
in the step (c), the boundary layer is formed by epitaxially growing a material, which contains the impurities of the second conductivity type and has a lattice match with the semiconductor substrate, on the side and bottom surfaces of the trench.

13. The method of claim 10, wherein
the boundary layer has a thickness of at least 5 nm, and contains at least 5×10¹⁹ cm⁻³ of the impurities of the second conductivity type.

14. The method of claim 10, wherein
in the step (d), a material, which contains p-type impurities as the impurities of the second conductivity type, and generates compressive strain of a gate length direction in a channel region formed in a portion corresponding to the gate electrode in the element formation region, is epitaxially grown as the silicon alloy layer.

15. The method of claim 14, wherein
the silicon alloy layer is made of silicon germanium.

16. The method of claim 10, wherein
in the step (d), a material, which contains n-type impurities as the impurities of the second conductivity type, and generates tensile strain of a gate length direction in a channel region formed in a portion corresponding to the gate electrode in the element formation region, is epitaxially grown as the silicon alloy layer.

17. The method of claim 16, wherein
the silicon alloy layer is made of silicon carbide.
